(19) United States
(12) Patent Application Publication
(10) Pub. No.: US 2013/0325390 A1
(43) Pub. Date: Dec. 5, 2013

(54) RF ESD DEVICE LEVEL DIFFERENTIAL VOLTAGE MEASUREMENT

(71) Applicants: Marcos Hernandez, San Jose, CA (US); Joseph G. Snider, Melrose, MA (US); Thomas J. Meuse, Tyngsboro, MA (US)

(72) Inventors: Marcos Hernandez, San Jose, CA (US); Joseph G. Snider, Melrose, MA (US); Thomas J. Meuse, Tyngsboro, MA (US)

(21) Appl. No.: 13/963,089

(22) Filed: Aug. 9, 2013

Related U.S. Application Data
(63) Continuation-in-part of application No. 13/436,353, filed on Mar. 30, 2012.

(51) Int. Cl. G01R 31/319

(52) U.S. Cl. CPC G01R 31/31924
USPC 702/117; 324/762.01

(57) ABSTRACT

A testing assembly for measuring voltage across a circuit during an electrostatic discharge event is provided. The assembly includes a high-frequency read-out device configured for coupling with an input of the circuit and coupling with an output of the circuit, each of the couplings including components configured for substantially blocking high-frequency electric signals while passing low frequency electric signals. A method of operation and a computer program product are also disclosed.

### BACKGROUND OF THE INVENTION

1. Field of the Invention

The invention disclosed herein relates to test equipment, in particular to equipment for evaluating voltage during equipment qualification.

2. Description of the Related Art

Electrostatic discharge (ESD) is one of the biggest threats to semiconductor reliability. The semiconductor devices are tested against industry standards such as ESDA, JEDEC, AEC, and Military. The industry standards specify test voltages and current waveforms that an ESD simulator must comply with to ensure repeatability and consistency for electrostatic discharge robustness of a given semiconductor device or integrated circuit (IC). During equipment qualification, the compliance standards include collecting a set of waveforms that contains the ESD voltages and current.

In recent years, it has become important to collect current information during device testing and not only during equipment simulation qualification. Collection of current waveform data while the device is under tests results in better ESD protection circuits that can be embedded into a semiconductor device. Current waveform data is measured using current probes (e.g., Tektronix CT1, CT2, and CT6). The current probes introduce few changes to the current waveforms and thus have a minimum impact in simulator performance.

One prior art technique for gathering voltage date is direct voltage measurement using an off the shelf voltage probe (e.g., Tektronix P2220 and P2221). The measurement accuracy has two major problems. First, the maximum bandwidth of the probe is <200 MHz and thus, the maximum voltage that can be measured is 300V (30V RMS). Second, the probe itself presents a capacitance of 17 pF which affects the waveform produced by an ESD simulator (specifications for 10x position).

Another prior art technique uses a voltage probe and a voltage divider, shown in FIG. 1. This circuit achieves higher voltage measurement capabilities (V_{R2}=Vᵢₙ(R₂/(R₁+R₂)) than the direct voltage probe method, but has bandwidth limitations due to the voltage probe and the resistor network used. An additional drawback is that it is impractical to change the dynamic range of the measurement.

Both of the aforementioned techniques are impractical to use close to a device-under-test (referred to herein as a “DUT”) because of their physical size. Thus, this calls for making the measurement away from the device-under-test (DUT), as shown in FIG. 2. However, as circuit impedance is very important for ESD testing and to make measurements that are meaningful for both current and voltage, measurements should be performed as close to the device-under-test (DUT) as possible.

Voltage waveform collection is more challenging. The voltages used for ESD are typically in the thousands of volts and can exceed +/−12,000V. A voltage probe introduces parasitic currents into the simulator circuit that alters the characteristics of the waveform produced. The frequency required to collect the waveform is above 500 MHz.

Thus, what are needed are methods and apparatus to collect accurate voltage information from a device during qualification.

### SUMMARY OF THE INVENTION

In one embodiment, a testing assembly for measuring voltage across a circuit during an electrostatic discharge event is provided. The assembly includes a high-frequency read-out device configured for coupling with an input of the circuit and coupling with an output of the circuit, each of the couplings including components configured for substantially blocking high-frequency electric signals while passing low frequency electric signals.

In another embodiment, a method for measuring voltage across a circuit during an electrostatic discharge event is provided. The method includes selecting a high-frequency read-out device configured for coupling with an input of the circuit and coupling with an output of the circuit, each of the couplings including components configured for substantially blocking high-frequency electric signals while passing low frequency electric signals; coupling the high-frequency read-out device to the circuit; and, measuring the voltage.

In yet another embodiment, a computer program product including machine readable instructions stored on machine readable media, the instructions including machine executable steps for testing a circuit. The computer program product includes instructions for providing an electrical pulse to the circuit, the pulse simulating an electrostatic discharge event; producing measurement data by measuring a voltage across the circuit, the measurement data collected by a high-frequency read-out device coupled to an input of the circuit and coupled to an output of the circuit, each of the couplings including components configured for substantially blocking high-frequency electric signals while passing low frequency electric signals; and, correcting the measurement data to provide voltage test results.

### BRIEF DESCRIPTION OF THE DRAWINGS

The features and advantages of the invention are apparent from the following description taken in conjunction with the accompanying drawings in which:

FIGS. 1 and 2 are schematic diagrams depicting embodiments of a prior art system;

FIGS. 3 through 5 are schematic diagrams providing exemplary system architectures for a measurement system according to the teachings herein;

FIG. 6 is a flowchart illustrating an exemplary method for performing measurements; and,

FIGS. 7 through 10 are graphs from an oscilloscope illustrating output signals of a voltage measurement circuit provided according to the teachings herein.

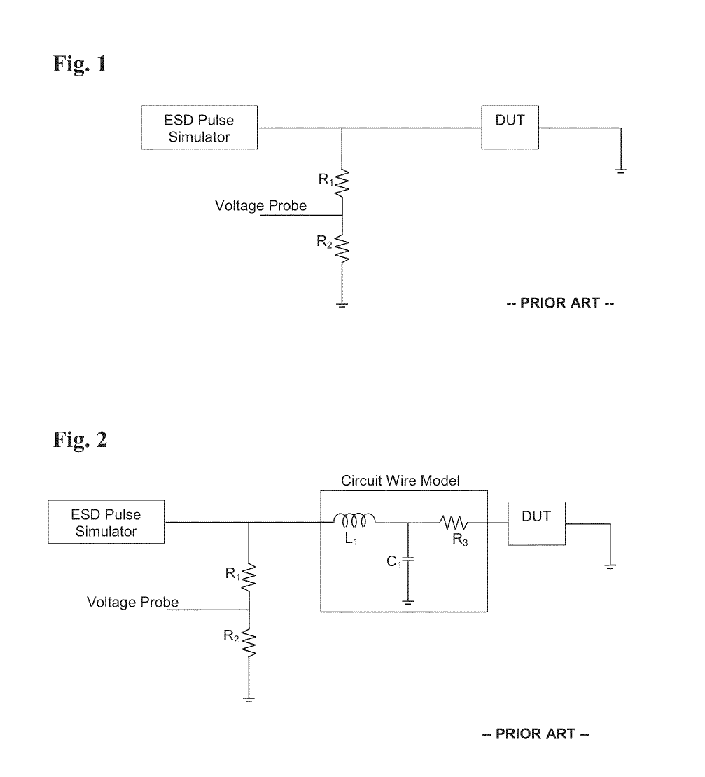

### DETAILED DESCRIPTION OF THE INVENTION

Disclosed herein are methods and apparatus for monitoring voltage of electrostatic discharge (ESD) for a semiconductor device or integrated circuit (IC) during equipment qualification. The methods and apparatus disclosed herein provide for collection of high-voltage and high-frequency waveforms while providing an insignificant impact (e.g., less than about 2%) upon electrical characteristics being tested. Accordingly, the methods and apparatus disclosed herein provide for greatly improved insight into electrical performance of a device-under-test (DUT).

As discussed herein, an “electrostatic discharge event” generally refers to an electrostatic pulse. As discussed herein, the electrostatic pulse is applied to an electronic device. For equipment qualification, the electronic device is referred to herein as a “device-under-test (DUT).” Examples of electronic devices that may be subjected to testing according to the teachings herein include at least one semiconductor component including a wafer level component, circuit and the like. Although the electronic device is referred to herein as a “device-under-test (DUT),” the electronic device may also be referred to simply as a “circuit.” Note that the use of the term “circuit” is not meant to be limiting of a given “device-under-test (DUT),” and is merely meant to designate an electrical component that has been selected for electrostatic testing.

Generally, an ESD pulse generator is configured to provide an electrical signal that mimics or simulates a desired type of electrostatic discharge. For example, the ESD pulse generator may be configured to provide a human-body model (HBM) output signal. The HBM signal is a commonly used model for characterizing susceptibility of an electronic device to damage that might occur when a human touches an electronic device. Other output signals that may be provided by the ESD pulse generator include: a charged-device model (CDM), a machine model (MM), a human-metal model (HMM), a transmission-line pulse (TLP), and any other type of model of electrostatic discharge that is deemed appropriate. Generally, aspects of models for electrostatic discharge simulation are defined in a variety of standards. Exemplary standards for modeling electrostatic discharge include the military (for example, MIL-STD-883 Method 3015), the Joint Electron Devices Engineering Council (JEDEC) Solid-State Technology Association (for example, JEDEC 22-A114-B) and other similar governmental bodies, standards associations and may further include third-party requirements (that is, a third-party model), such as those imposed by a manufacturer or end-user.

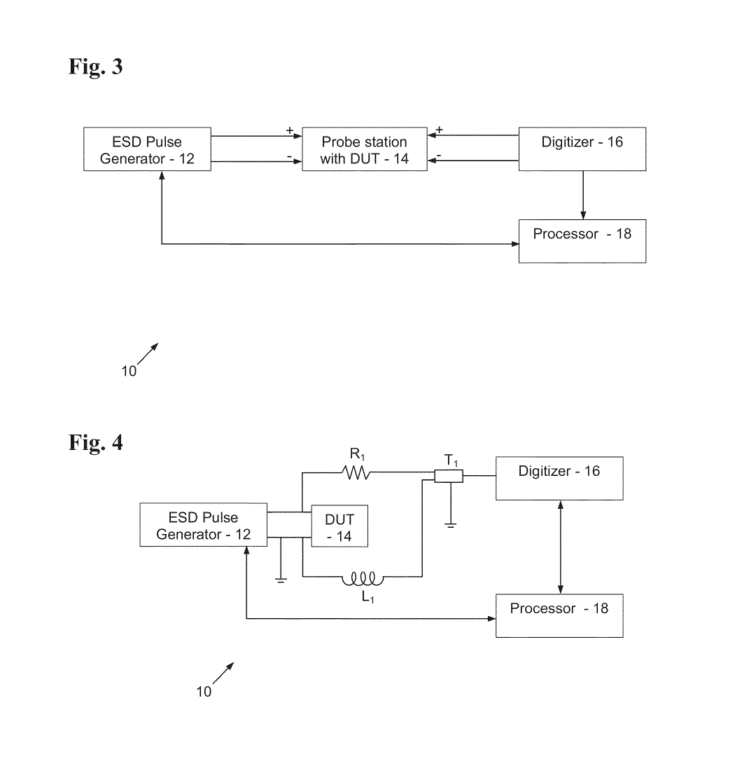

FIG. 3 illustrates a functional block diagram of an embodiment of an exemplary tester 10. The exemplary tester 10 includes an electro-static discharge (ESD) pulse generator 12, a probe station, 14, a high-frequency digitizer 16 (e.g. an oscilloscope), and a processor 18. The ESD pulse generator 12 and high-frequency digitizer 16 are differentially connected to the probe station 14. The probe station 14 supports the device-under-test (referred to herein as a “DUT”).

In operation, voltage measurement is taken using a differential probe placed across the device-under test (DUT) 14 to ensure an accurate measurement. Generally, the probe selected exhibits high-impedance, (e.g. greater than 2,500 Ohms), while ESD protection structures for the device-under-test (DUT) 14 have a resistance of less than about 5 Ohms. A high-voltage waveform is collected using high-frequency coaxial probes and 50 Ohm coaxial lines to interface with high-frequency read-out 16, (e.g. a digitizer, such as an oscilloscope). The use of 50 Ohm coaxial lines and needles provide the ability to use 50 Ohm attenuators readily available in industry, and providing high attenuation with low insertion loss and thus allowing voltage measurements in the thousands of volts.

In some embodiments, the current and voltage probes are separated from each other, thereby eliminating impedance contribution of wiring and contact resistances. Only a voltage drop across the DUT 14 is measured, and not a voltage across the attached coaxial probes. Thus, calculated resistance is substantially indicative of resistance of the device-under-test (DUT), while resistance in other components may be neglected.

That is, as the digitizer probes carry a low current, resistance of the probes does not substantially interfere with measurement. A length of cables for the probes connecting the oscilloscope across the device-under-test (DUT) will insignificantly impact voltage, resulting in a voltage waveform that is very nearly the same as if the tester 10 were connected directly across the DUT 14. Generally, each coupling to the device-under-test (DUT) (for example, the current and voltage probes) includes components configured for substantially blocking high-frequency electric signals while passing low frequency electric signals.

Similarly, a voltage drop across the main current-carrying cables of the ESD pulse generator 12 are an insubstantial component of measurements measured by the read-out 16, and may be neglected in the resistance calculation.

Generally, the tester 10 includes a feedback loop between the processor 18 and the ESD pulse generator 12. Accordingly, processor 18 may include components necessary for controlling the ESD pulse generator 12 including, for example, communications interface components, sensors, a user interface, software (that is, machine executable instructions stored on machine readable media, the instructions including instructions for implementing methods disclosed herein), memory, storage, and other computing equipment determined to be appropriate for use of the tester 10. Additionally, the processor 18 may be configured for receiving measurement data and performing any corrections to provide measurement results.

In some embodiments, the tester 10 does not include a feedback loop between the processor 18 and the ESD pulse generator 12. For example, in some embodiments, the tester 10 is configured for manual operation such as by a technician or engineer.

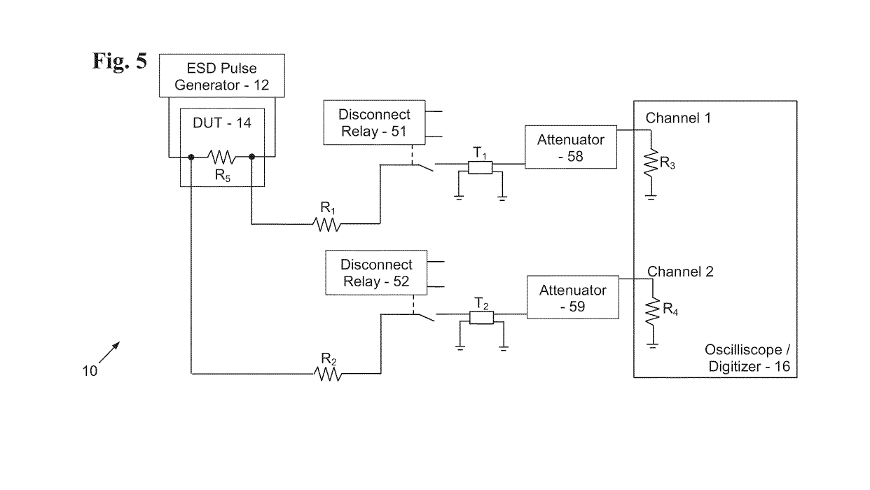

FIGS. 4 and 5 are schematic circuit diagrams providing an overview of the architecture for additional embodiments of the tester 10. As shown in FIG. 4, a radio frequency (RF) choke may be used to isolate the device-under-test (DUT) from ground, since the ESD signal is very short in duration. This preserves the current waveform and allows for grounding of the terminal. In this example, the tester 10 may be configured to test for waveforms that are characteristic of HBM waveforms or HMM waveforms. In this example, resistor, R₁, is implemented as a 1,500 Ohm (Ω) resistor, and is electrically coupled to a first terminal of the device-under-test (DUT). Use of resistor, R₁, provides for electrically withstanding the ESD pulse, and therefore may be referred to as an “withstand resistor.” In this example, inductor, L₁, is implemented as a 2.2 μH inductor and is electrically coupled to a second terminal of the device-under-test (DUT), and may be referred to herein simply as one embodiment of a “choke.”

Generally, and as a matter of convention, a choke is a coil made of insulated wire, often wound on a magnetic core, and is used as a passive inductor that blocks (or substantially blocks) higher-frequency alternating current (AC) while passing signals of much lower frequency as well as signals that are direct current (DC). Accordingly, a choke inductor may be selected to exhibit appropriate impedance (which is largely determined by reactance, and is proportional to frequency).

Another embodiment of the tester 10 is shown in FIG. 5. In FIG. 5, the tester 10 includes a mechanism for disconnecting voltage sense probes. In this embodiment, disconnect relays 51, 52 include 50 Ohm (Ω) switches that isolate the voltage measurement system and allow a curve trace of the device-under-test (DUT) to be taken without the influence of the impedance of the measurement system.

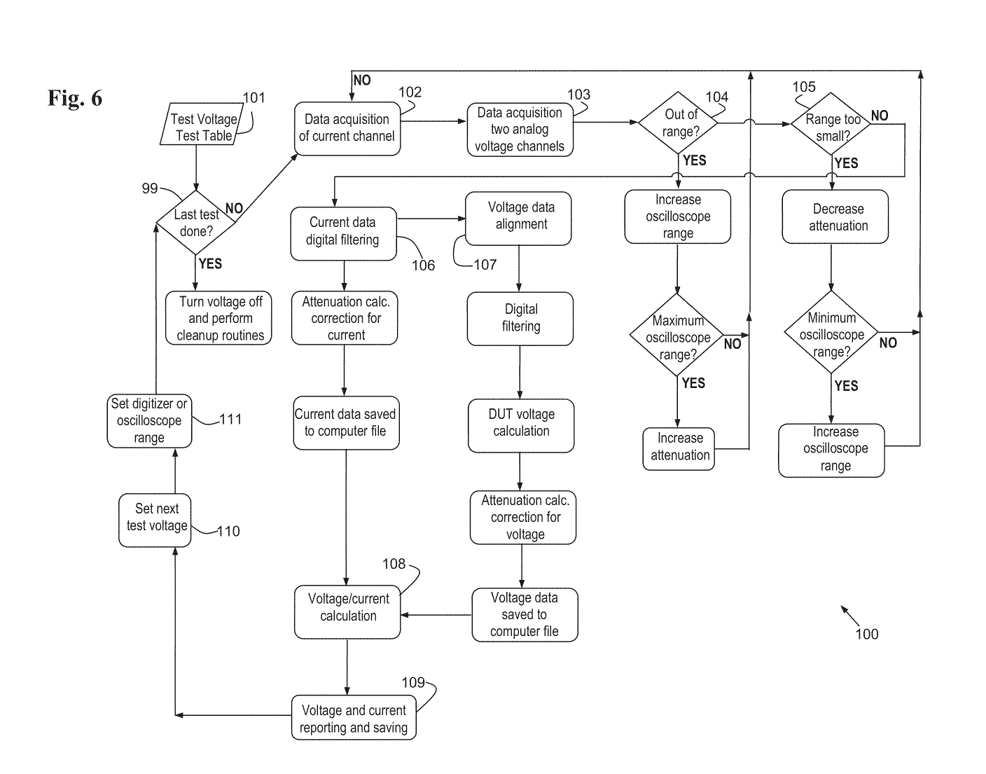

An overview of an algorithm for implementation in software is now presented, and then discussed in greater detail with regards to FIG. 6.

Once the tester 10 has been set up for testing, raw data acquisition is performed for two voltage channels and one current channel. Once the data has been acquired, the data is checked to make sure it is in the range of measurement. The data may also be checked to ensure it does not saturate the digitizer or oscilloscope or use too few of the digitizer bits. In one example, an acceptable range for the data is established as between about 35% and about 70% of the scale selected and the digitizer or oscilloscope. Subsequently temporal alignment of the two data sets is performed. That is, voltage data from a first channel is aligned with voltage data from the second channel to ensure alignment of sampling time for each channel of data.

Once the first channel and the second channel have been aligned, a voltage calculation is performed. Voltage across the device-under-test (DUT) may be calculated according to Eq. 1, below. Voltage may be corrected for attenuation according to Eq. 2, and currents may be corrected for attenuation according to Eq. 3. Eqs. 1-3:

V_{DUT}=V_{Channel 1}−V_{Channel 2} (1);

V_{DUT CORRECTED}=V_{DUT}*Attenuation*R₁/R₂ (2);

I_{DUT CORRECTED}=I_{DUT}*Attenuation (3).

Voltage and current data for the device-under-test (DUT) is then reported and/or stored. A output voltage of the ESD pulse generator 12 may then be adjusted and the read-out 16 (for example, a digitizer or oscilloscope) prepared for acquisition. This process is provided with greater detail in FIG. 6.

Referring to FIG. 6, an exemplary method 100 for testing a device is described in a flow chart. The method 100 will start with reference to a testing plan. The testing plan is maintained in a test table, and may include a plurality of current settings and voltage settings protesting the device. A first step 101 references the test table and identifies initial settings for a test sequence.

As the method 100 may be performed iteratively, step 99 may be included to test for completion of the testing plan. In this example, testing begins with step 102 where current data is acquired from the device-under-test (DUT). Subsequently, in step 103, voltage data is acquired from the device-under-test (DUT). In branches that begin at steps 104 and 105, the data are compared to settings of the oscilloscope, and the oscilloscope is adjusted appropriately. After any appropriate adjustments are completed, current data is corrected by following a branch that begins at step 106. Similarly, voltage data is corrected by following a branch that begins at step 107. At step 108, voltage and current results are calculated. At step 109, the results are stored and/or reported as desired. At step 110, the pulse generator is stepped to the next appropriate current and/or voltage setting as provided in the test table, and in step 111 the oscilloscope is also adjusted appropriately.

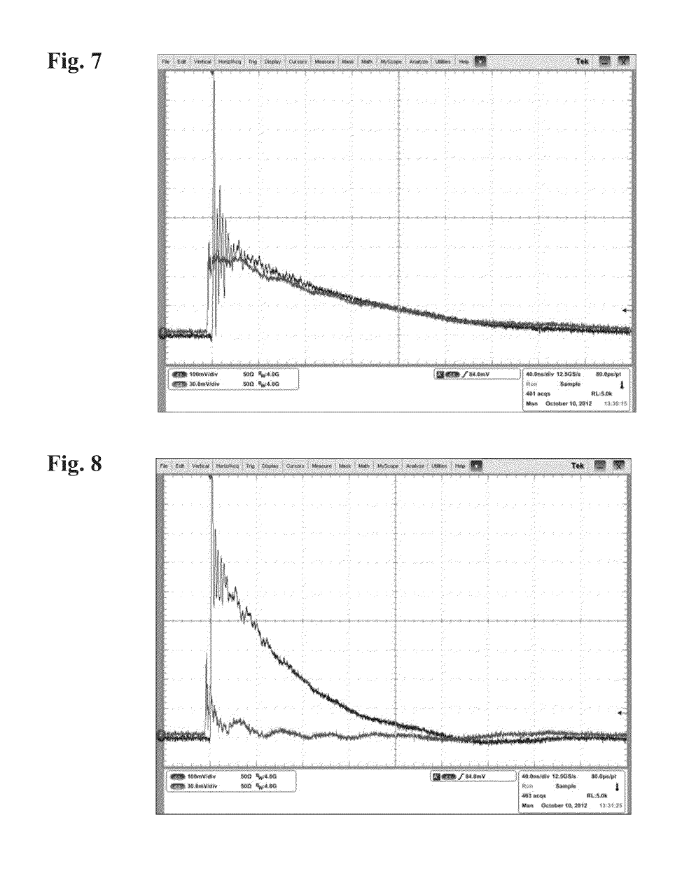

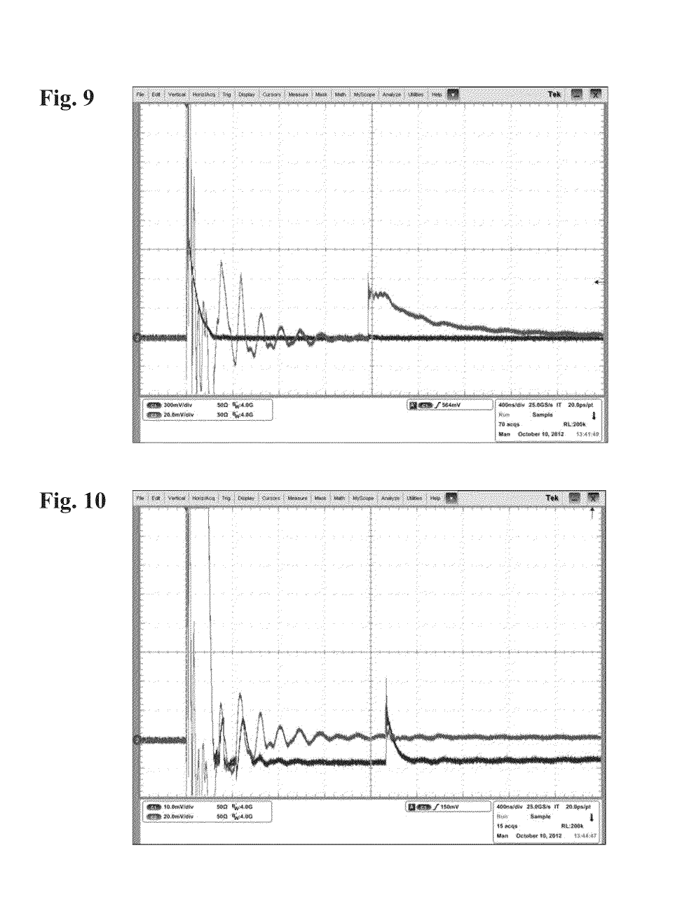

Referring now to FIGS. 7-10, exemplary waveforms outputted by the tester to an oscilloscope are shown. In these examples, a 500 Ohm (Ω) withstand resistor was used.

Having thus introduced aspects of the invention, some additional aspects and embodiments are now presented.

Advantageously, the techniques disclosed herein provide for electrostatic discharge testing for discrete devices (package level use) as well as for silicon wafer probing (wafer level use). The techniques make use of high-frequency components in a combination of high impedance resistors and attenuators that provide for differential voltage measurements of stress signals in excess of plus or minus 12,000 V. Data acquisition may be performed using a high-speed digitizer such as an oscilloscope, but other devices may be used. Signals acquired may be stored and analyzed using software to automate (or at least partially automate) determination of voltage drop across the device-under-test (DUT). Use of information made available by techniques disclosed herein in conjunction with known techniques (such as for measuring current) provides for a more thorough characterization of each device-under-test (DUT).

Although embodiments disclosed herein make use of components rated at 50 ohms, this is not a requirement. That is, while 50 ohm components are commonly available commercially, the teachings herein are not limited in this manner. Generally, apparatus used in the measurement system are selected and configured such that impedance of the measurement system does not influence the measurement process. More specifically, by using high impedance probes and related components with a high-frequency digitizer, separation of an output signal from the device-under-test (DUT) (which exhibits, for example, a low resistance of less than about 5 ohms) is achievable. Stated another way, components of the test apparatus are of high impedance when compared with the device-under-test (DUT), and therefore insubstantially influence data produced by the voltage measurements.

By employing the techniques herein, it is possible to obtain a resolution of about 1 V within the range from about 0 V to about 4000 V or more. In short, apparatus disclosed herein collects very high-voltage, high-frequency waveforms with little impact to the electrical characteristics of the simulator circuit, and therefore preserve test data waveforms to industry standards.

The high-frequency read-out 16 may be a digitizer, and oscilloscope, or any other suitable device. It is not necessary that the read-out 16 be digital.

Various other components may be included and called upon for providing for aspects of the teachings herein. For example, additional components, combinations of components and/or omission of components may be used to provide for added embodiments that are within the scope of the teachings herein.

When introducing elements of the present invention or the embodiment(s) thereof, the articles “a,” “an,” and “the” are intended to mean that there are one or more of the elements. Similarly, the adjective “another,” when used to introduce an element, is intended to mean one or more elements. The terms “including” and “having” are intended to be inclusive such that there may be additional elements other than the listed elements.

While the invention has been described with reference to exemplary embodiments, it will be understood by those skilled in the art that various changes may be made and equivalents may be substituted for elements thereof without departing from the scope of the invention. In addition, many modifications will be appreciated by those skilled in the art to adapt a particular instrument, situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A testing assembly for measuring voltage across a circuit during an electrostatic discharge event, the assembly comprising:
a high-frequency read-out device configured for coupling with an input of the circuit and coupling with an output of the circuit, each of the couplings comprising components configured for substantially blocking high-frequency electric signals while passing low frequency electric signals.

2. The assembly as in claim 1, wherein the read-out device comprises at least one of a digitizer and an oscilloscope.

3. The assembly as in claim 1, further comprising an electrostatic pulse generator for providing the electrostatic discharge event.

4. The assembly as in claim 3, wherein the electrostatic pulse generator may be configured for providing a signal that conforms to one of a human-body model (HBM), a charge device model (CDM), a machine model (MM), a human-metal model (HMM) and a transmission-line pulse (TLP), and a third-party model as an output.

5. The assembly as in claim 1, wherein at least one of the couplings comprises a high-impedance inductor.

6. The assembly as in claim 1, wherein at least one of the couplings comprises a withstand resistor.

7. The assembly as in claim 1, further comprising a processor configured for controlling at least one of an electrostatic pulse generator and the high-frequency read-out device.

8. The assembly as in claim 7, wherein the processor is further configured for receiving data and providing results.

9. The assembly as in claim 1, wherein each of the read-out device and the couplings comprise substantially equivalent impedance.

10. A method for measuring voltage across a circuit during an electrostatic discharge event, the method comprising:
selecting a high-frequency read-out device configured for coupling with an input of the circuit and coupling with an output of the circuit, each of the couplings comprising components configured for substantially blocking high-frequency electric signals while passing low frequency electric signals;
coupling the high-frequency read-out device to the circuit; and, measuring the voltage.

11. The method as in claim 10, further comprising applying an electrostatic discharge event to circuit.

12. The method as in claim 11, wherein the electrostatic discharge event is between about minus 12,000 V and plus 12,000 V.

13. The method as in claim 10, wherein the selecting comprises choosing a read-out device and couplings that exhibit substantially equivalent impedance.

14. A computer program product comprising machine readable instructions stored on machine readable media, the instructions comprising machine executable steps for testing a circuit by:
providing an electrical pulse to the circuit, the pulse simulating an electrostatic discharge event;
producing measurement data by measuring a voltage across the circuit, the measurement data collected by a high-frequency read-out device coupled to an input of the circuit and coupled to an output of the circuit, each of the couplings comprising components configured for substantially blocking high-frequency electric signals while passing low frequency electric signals; and,
correcting the measurement data to provide voltage test results.

15. The computer program product as in claim 14, further comprising steps for adjusting a property of the electrical pulse.

16. The computer program product as in claim 14, further comprising steps for controlling the read-out device.

17. The computer program product as in claim 14, further comprising steps for temporally aligning measurement data from a first channel with measurement data from a second channel.

18. The computer program product as in claim 14, further comprising steps for correcting measurement data according to the attenuation values.

19. The computer program product as in claim 14, further comprising steps for determining current test results.

20. The computer program product as in claim 14, further comprising steps for at least one of storing and reporting at least one of measurement data, voltage test results and current test results.
